(19) United States
(12) Patent Application Publication
(10) Pub. No.: US 2024/0286176 A1
(43) Pub. Date: Aug. 29, 2024

(54) SUBSTRATE CLEANING APPARATUS

(71) Applicant: KCTECH CO., LTD., Gyeonggi-do (KR)

(72) Inventors: Keun Woo LEE, Gyeonggi-do (KR); Dae Jung KANG, Gyeonggi-do (KR); Byeong Jo PARK, Gyeonggi-do (KR)

(73) Assignee: KCTECH CO., LTD., Gyeonggi-do (KR)

(21) Appl. No.: 18/469,540

(22) Filed: Sep. 18, 2023

(30) Foreign Application Priority Data
Feb. 24, 2023 (KR) 10-2023-0024832

(51) Int. Cl. B08B 5/04; B08B 3/02; B08B 5/02; H01L 21/67

(52) U.S. Cl. CPC B08B 5/043; B08B 3/022; B08B 5/023; H01L 21/67051; B08B 2203/0211

(57) ABSTRACT

A substrate cleaning apparatus includes a stage on which a substrate is placed, a support unit configured to support the substrate and to rotate the substrate, and a cleaning unit configured to spray a dual fluid to clean the substrate, wherein the cleaning unit may include a spray nozzle including a spray hole opened toward the stage and configured to spray a dual fluid through the spray hole, a cover that may include an inlet surrounding at least a partial area of an outer circumferential surface of the spray hole, that may surround at least a partial area of an outer circumferential surface of the spray nozzle, and that may be spaced apart from the spray nozzle by a predetermined distance, and an air flow passage formed in a space between the cover and the spray nozzle and through which air sucked from the inlet flows.

### CROSS-REFERENCE TO RELATED APPLICATION

This application claims the benefit of Korean Patent Application No. 10-2023-0024832 filed on Feb. 24, 2023, in the Korean Intellectual Property Office, the entire disclosure of which is incorporated herein by reference for all purposes.

### BACKGROUND

### 1. Field of the Invention

One or more embodiments relate to a substrate cleaning apparatus.

### 2. Description of the Related Art

In manufacturing a substrate, a chemical mechanical polishing (CMP) process including polishing, buffing and/or cleaning is required. In the CMP process of a substrate, a process of polishing a target surface of the substrate with a polishing pad is required and an abrasive in the form of slurry may also be used to increase polishing performance.

Since the polishing process of the CMP process physically abrades the substrate, foreign materials such as wear fragment, fine dust, and residual slurry remain after the polishing process. A substrate cleaning apparatus performs a process of cleaning a substrate in order to remove such foreign materials after the polishing process.

In a substrate cleaning process, a substrate cleaning apparatus may use a dual fluid spray. For example, a dual fluid spray is a method of simultaneously spraying high-pressure gas and a liquid such as de-ionized water (DIW). The dual fluid spray may pulverize DIW in a liquid state into micro-particles and make DIW collide with the substrate. The high-pressure gas and the DIW in units of the micro-particles remove foreign materials remaining on a substrate.

The above description has been possessed or acquired by the inventor(s) in the course of conceiving the present disclosure and is not necessarily an art publicly known before the present application is filed.

### SUMMARY

An aspect of an embodiment is to provide a substrate cleaning apparatus that may prevent secondary contamination of a substrate by preventing particles of de-ionized water (DIW) or foreign materials scattered by a dual fluid spray from being adsorbed on a surface of the substrate.

An aspect of an embodiment is to provide a substrate cleaning apparatus that may improve substrate cleaning capability and increase a drying yield by improving nozzle hardware of a dual fluid spray.

According to an aspect, there is provided a substrate cleaning apparatus including a stage on which a substrate is placed, a support unit configured to support the substrate and to rotate the substrate, and a cleaning unit configured to spray a dual fluid to clean the substrate, wherein the cleaning unit may include a spray nozzle including a spray hole opened toward the stage and configured to spray a dual fluid through the spray hole, a cover that may include an inlet surrounding at least a partial area of an outer circumferential surface of the spray hole, that may surround at least a partial area of an outer circumferential surface of the spray nozzle, and that may be spaced apart from the spray nozzle by a predetermined distance, and an air flow passage formed in a space between the cover and the spray nozzle and through which air sucked from the inlet flows.

The inlet may surround an entire outer circumferential surface of the spray hole.

The inlet may be disposed relatively closer to the stage than the spray hole.

The cover may include a distal end portion extending to a position closer to the stage than the spray nozzle.

The cleaning unit may include a gas line connected to the spray nozzle and configured to supply gas to the spray nozzle, and a liquid line connected to the spray nozzle and configured to supply DIW to the spray nozzle.

The cover may include a through hole through which the gas line and the liquid line pass, and a sealing member provided in the through hole.

The substrate cleaning apparatus may further include a chamber configured to accommodate the stage in the chamber.

The cleaning unit may be configured to pass air sucked through the inlet through the air flow passage and discharge air to an outside of the chamber.

The stage may include an outlet that may be disposed in a direction surrounding the substrate disposed on the support unit and is configured to suck air from the stage.

The stage may include a guard ring surrounding the substrate disposed on the support unit and extending to an upper part of the stage.

Additional aspects of embodiments will be set forth in part in the description which follows and, in part, will be apparent from the description, or may be learned by practice of the disclosure.

According to an embodiment, a substrate cleaning apparatus may prevent secondary contamination of a substrate by absorbing again DIW or foreign materials scattered by a cleaning nozzle.

In addition, according to an embodiment, a substrate cleaning apparatus may improve substrate cleaning capability and increase a drying yield of a substrate by improving a structure of a cleaning nozzle.

The effects of a substrate cleaning apparatus according to an embodiment are not limited to the above-mentioned effects, and other unmentioned effects can be clearly understood from the following description by one of ordinary skill in the art.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a perspective view of a substrate cleaning apparatus according to an embodiment;

FIG. 2 is a side view of the substrate cleaning apparatus according to an embodiment;

FIG. 3 is a side view illustrating fluid flow of the substrate cleaning apparatus according to an embodiment;

FIG. 4 is an enlarged view of the substrate cleaning apparatus according to an embodiment; and

FIG. 5 is an enlarged view of the substrate cleaning apparatus according to an embodiment.

### DETAILED DESCRIPTION

Hereinafter, embodiments will be described in detail with reference to the accompanying drawings. However, various alterations and modifications may be made to the embodiments. Here, the embodiments are not meant to be limited by the descriptions of the present disclosure. The embodiments should be understood to include all changes, equivalents, and replacements within the idea and the technical scope of the disclosure.

The terminology used herein is for the purpose of describing particular embodiments only and is not to be limiting of the embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. Terms defined in dictionaries generally used should be construed to have meanings matching with contextual meanings in the related art and are not to be construed as an ideal or excessively formal meaning unless otherwise defined herein.

When describing the embodiments with reference to the accompanying drawings, like reference numerals refer to like components and a repeated description related thereto will be omitted. In the description of the embodiments, a detailed description of well-known related structures or functions will be omitted when it is deemed that such description will cause ambiguous interpretation of the present disclosure.

In addition, terms such as first, second, A, B, (a), (b), and the like may be used to describe components of the embodiments. Each of these terms is not used to define an essence, order or sequence of a corresponding component but used merely to distinguish the corresponding component from other component(s). It should be noted that if one component is described as being “connected”, “coupled” or “joined” to another component, the former may be directly “connected,” “coupled”, and “joined” to the latter or “connected”, “coupled”, and “joined” to the latter via another component.

The same name may be used to describe an element included in the embodiments described above and an element having a common function. Unless disclosed to the contrary, the descriptions of any one embodiment may be applied to other embodiments and thus, duplicated descriptions will be omitted.

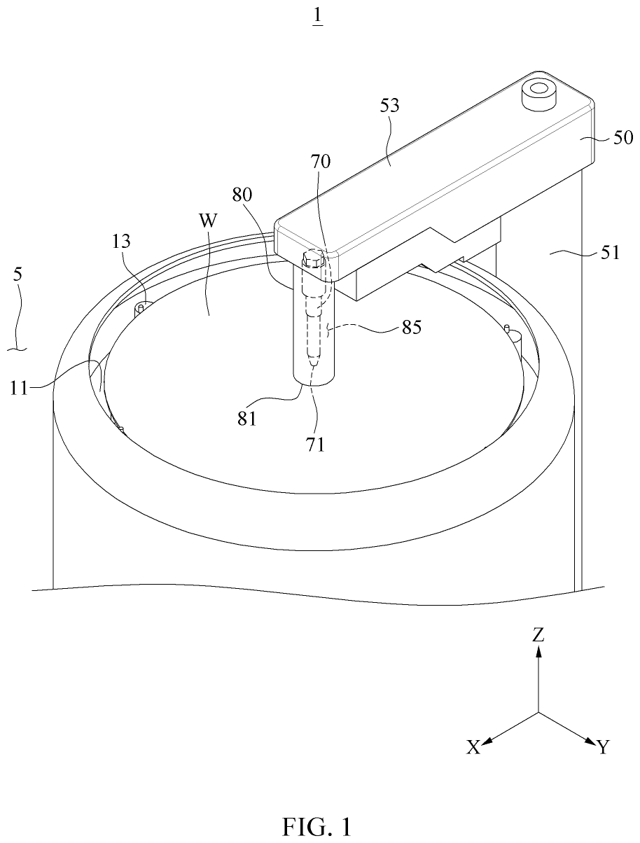

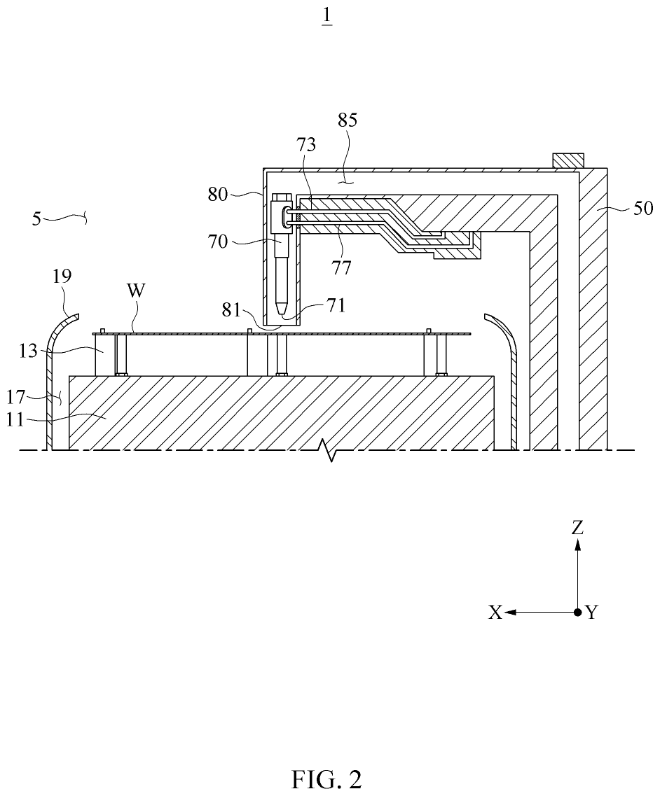

FIG. 1 is a perspective view of a substrate cleaning apparatus 1 according to an embodiment, and FIG. 2 is a side view of the substrate cleaning apparatus 1 according to an embodiment.

Referring to FIGS. 1 and 2, in an embodiment, the substrate cleaning apparatus 1 may be used for a chemical mechanical polishing (CMP) process of a substrate W.

For example, the substrate W may be a silicon wafer for manufacturing a semiconductor device. However, the type of a substrate is not limited thereto. For example, a substrate may include glass for a flat panel display (FPD) device such as a liquid crystal display (LCD) and a plasma display panel (PDP).

In an embodiment, the substrate cleaning apparatus 1 may clean the substrate W. The substrate cleaning apparatus 1 may remove foreign materials remaining on the substrate W after a polishing process of the substrate W. For example, the substrate W may be physically polished by a polishing pad, and residual materials may adhere to a surface of the substrate W, or materials (e.g., slurry) used in the polishing process may remain on the surface of the substrate W. In the cleaning process of the substrate W after the polishing process, the substrate cleaning apparatus 1 may remove foreign materials remaining on the substrate W and may clean the substrate W, by spraying a cleaning liquid or the like to the substrate W while supporting the substrate W.

In an embodiment, a stage 11 may be an area where the substrate W is placed and a substrate cleaning process is performed. A support unit 13 to support the substrate W may be installed on the stage 11. The support unit 13 may rotate the substrate W clockwise or counterclockwise while supporting the lower surface or side surface of the substrate W.

In an embodiment, a substrate cleaning unit 50 may include a chamber 5, which is a space for accommodating the stage 11 in the chamber 5. The chamber 5 may separate the stage 11 from an external environment. In an external environment, dust, fine dust, moisture, or foreign materials floating in the air may be present, and when the substrate W is exposed in such an environment, the substrate W may be contaminated. The chamber 5 may form and maintain an environment suitable for the substrate W to be cleaned by controlling a cleaning environment such as internal temperature, humidity, or air condition.

In an embodiment, the stage 11 may include at least a portion of an outlet 17 and a guard ring 19. The outlet 17 may be disposed in a direction surrounding the substrate W disposed on the support unit 13 and may suck a dual fluid or foreign materials scattered from the substrate W.

For example, the outlet 17 may be formed in a continuous structure surrounding the outer circumferential surface of the substrate W, or the outlet 17 may be formed in plurality and thus the outlets 17 may be spaced apart from each other. The outlet 17 may suck air from the stage 11 toward a surface to be cleaned of the substrate W and may thus suck de-ionized water (DIW) or foreign materials on the upper surface of the substrate W. Air sucked in through the outlet 17 may be discharged to the outside of the chamber 5, with air sucked in through an inlet 81.

In an embodiment, the guard ring 19 may have a shape extending upward from the outside of the stage 11 while surrounding the substrate W disposed on the support unit 13. The guard ring 19 may have an inclined or rounded shape in a direction toward the substrate W. The guard ring 19 may guide an air flow direction inside the stage 11 and may protect the substrate W.

In an embodiment, the cleaning unit 50 may spray a cleaning material (e.g., a cleaning liquid or cleaning gas) to clean the substrate W. In various embodiments of the present disclosure, the cleaning unit 50 spraying a dual fluid is described as an example, but embodiments are not limited thereto in actual implementation.

In an embodiment, a dual fluid may be high-pressure gas (e.g., nitrogen gas) and a liquid (e.g., DIW). For example, in a spraying process, DIW may be pulverized into micro-particles and accelerated by high-pressure gas, and such DIW and high-pressure gas may collide with a substrate to remove foreign materials such as particles, pad residual materials, slurry, and the like that remained on the substrate.

In an embodiment, the cleaning unit 50 may include a hand unit 53 and an arm unit 51. The arm unit 51 may support the hand unit 53 and may rotate and/or move the hand unit 53. For example, the hand unit 53 may rotate clockwise or counterclockwise within a predetermined range with the arm unit 51 as the rotation axis.

In an embodiment, in the cleaning unit 50, a spray nozzle 70 may be provided inside the hand unit 53. The spray nozzle 70 may include a spray hole 71 opened toward the stage 11. The spray nozzle 70 may spray a dual fluid through the spray hole 71. For example, in the hand unit 53, the spray hole 71 may be provided in one end portion (e.g., an end portion facing the stage 11) of the hand unit 53 to spray a dual fluid.

In an embodiment, the inlet 81 may be provided in an end portion of the hand unit 53 of the cleaning unit 50 to suck dual fluids, floating materials, or surrounding air. The cleaning unit 50 may include a cover 80 surrounding at least a partial area of the outer circumferential surface of the spray nozzle 70. The cover 80 may include the inlet 81 surrounding at least a partial area of the outer circumferential surface of the spray hole 71.

For example, the inlet 81 may have a larger area than the spray hole 71, may be disposed to overlap with at least a partial area of the spray hole 71 or to surround at least a partial area of the spray hole 71. Through the inlet 81, the cleaning unit 50 may suck air in a direction facing the stage 11.

In an embodiment, the cover 80 may be spaced apart from the spray nozzle 70 by a predetermined distance. An air flow passage 85 may be formed in a space between the cover 80 and the spray nozzle 70. Air sucked from the inlet 81 may flow through the air flow passage 85. The air flow passage 85 may be formed through the hand unit 53 and the arm unit 51 and may be connected, for example, to the outside of the chamber 5 from the inlet 81 through the hand unit 53 and the arm unit 51.

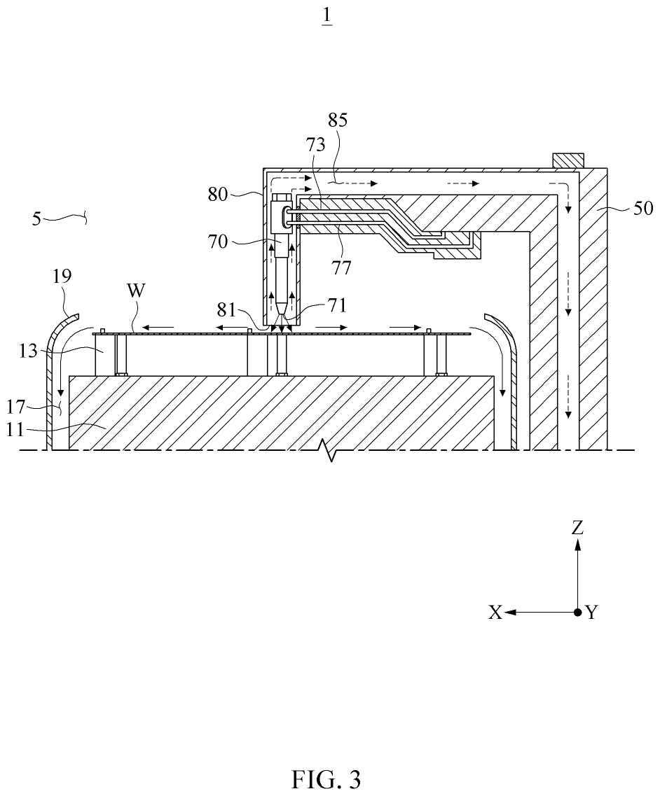

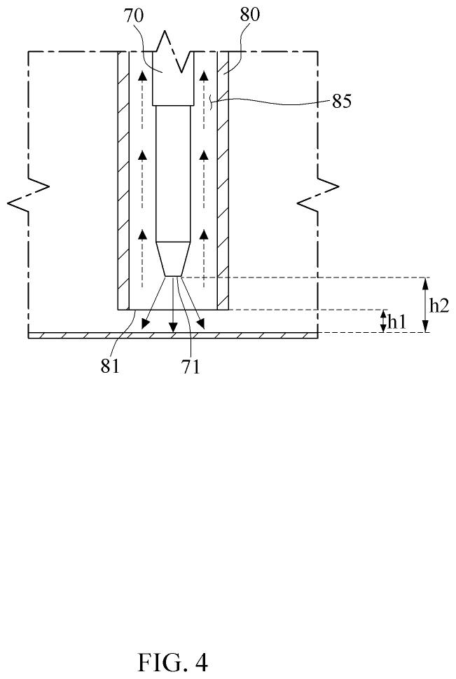

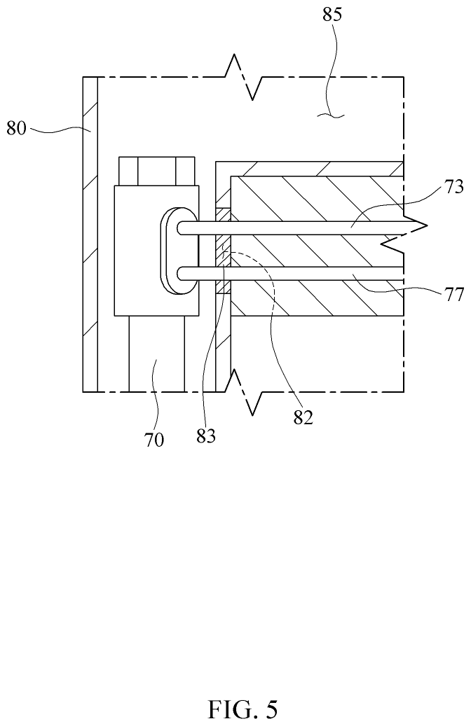

FIG. 3 is a side view illustrating fluid flow of the substrate cleaning apparatus 1 according to an embodiment, FIG. 4 is an enlarged view of the substrate cleaning apparatus 1 according to an embodiment, and FIG. 5 is an enlarged view of the substrate cleaning apparatus 1 according to an embodiment.

Referring to FIGS. 3, 4, and 5, the substrate cleaning apparatus 1 according to an embodiment may spray a dual fluid through the spray nozzle 70 and may suck air around the stage 11 through the inlet 81.

In an embodiment, the inlet 81 may have a shape surrounding at least a partial area of the outer circumferential surface of the spray hole 71 and may have a shape, for example, surrounding an entire area of the spray hole 71, as shown in FIG. 3. The inlet 81 may suck air around the stage 11 and around the spray hole 71.

In an embodiment, the spray hole 71 may spray a dual fluid at relatively high pressure, and the inlet 81 may suck surrounding air at relatively low pressure. Accordingly, most of the dual fluid sprayed through the spray hole 71 may be sprayed to the substrate W of the stage 11, and the inlet 81 may mainly suck gas or DIW fluid bounced off from the substrate W and foreign materials scattered by a dual fluid.

In an embodiment, when the inlet 81 is not included, DIW or foreign materials scattered from the substrate W may be adsorbed to the substrate W again, and the substrate W may be contaminated or defects may occur. In various embodiments of the present disclosure, the cleaning unit 50 may clean a specific position of the substrate W through the spray hole 71 and the inlet 81 and at the same time, by sucking foreign materials, adsorption of DIW or foreign materials on the substrate W may be reduced or prevented, and thus, the drying efficiency of the substrate W may be improved and the yield of the substrate W may be improved.

In an embodiment, the inlet 81 may be disposed relatively closer to the stage 11 than the spray hole 71. Air sucked through the inlet 81 may pass through the air flow passage 85 provided between the cover 80 and the spray nozzle 70. The cleaning unit 50 may discharge air sucked in through the inlet 81 to the outside of the stage 11 and further to the outside of the chamber 5 by passing air through the air flow passage 85. The cleaning unit 50 may improve or maintain a dry environment inside the chamber 5 by discharging the sucked air to the outside.

For example, as shown in FIG. 4, based on an arbitrary height of the stage 11, the height to the inlet 81 may be a first height h1, the height to the spray hole 71 may be a second height h2, and the first height h1 may be relatively less than the second height h2. Alternatively, in an embodiment, the distal end portion of the cover 80 may extend to a position closer to the stage 11 than the spray nozzle 70.

For example, based on an arbitrary height of the stage 11, the height to the distal end portion of the cover 80 may be a first height h1, the height to the distal end portion of the spray nozzle 70 may be a second height h2, and the first height h1 may be relatively less than the second height h2.

In an embodiment, by the disposition of the inlet 81 closer to the stage 11 than the spray hole 71, or by the extension of the cover 80 closer to the stage 11 than the spray nozzle 70, the inlet 81 may more efficiently suck air of the stage 11 with relatively small pressure, or may effectively suck a dual fluid or foreign materials sprayed from the spray hole 71 and scattered from a substrate.

In an embodiment, the cleaning unit 50 may include a gas line 73 and a liquid line 77, each connected to the spray nozzle 70. The gas line 73 may supply gas (e.g., nitrogen) to the spray nozzle 70, and the liquid line 77 may supply a liquid (e.g., DIW) to the spray nozzle 70. The spray nozzle 70 may be a dual fluid spray nozzle that simultaneously sprays gas and a liquid delivered from the gas line 73 and the liquid line 77 to a substrate.

In an embodiment, the cover 80 may include a through hole 82 and a sealing member 83. The through hole 82 may be an opening port through which the gas line 73 and the liquid line 77 pass, so that the gas line 73 and the liquid line 77 may be connected from the outside of the cover 80 to the spray nozzle 70 inside the cover 80. In FIG. 5, the through hole 82 is implemented as a single hole, but in actual implementation, the through hole 82 may be implemented as a plurality of holes to pass each of the gas line 73 and the liquid line 77.

In an embodiment, the sealing member 83 may be provided in the through hole 82. The sealing member 83 may substantially seal the through hole 82. Since the air flow passage 85 is formed inside the cover 80 and air of the air flow passage 85 needs to be discharged to the outside of the chamber 5, the inside and outside of the cover 80 needs to be substantially sealed except for the inlet 81. The sealing member 83 may seal the through hole 82 through which the gas line 73 and the liquid line 77 pass, preventing air of the air flow passage 85 from exposure to the outside of the cover 80 or air pressure of the air flow passage 85 from decreasing.

While the embodiments are described with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order, and/or if components in a described system, architecture, device, or circuit are combined in a different manner, or replaced or supplemented by other components or their equivalents.

Therefore, other implementations, other embodiments, and equivalents to the claims are also within the scope of the following claims.

What is claimed is:

1. A substrate cleaning apparatus comprising:
a stage on which a substrate is placed;
a support unit configured to support the substrate and to rotate the substrate; and
a cleaning unit configured to spray a dual fluid to clean the substrate;
wherein the cleaning unit comprises:
a spray nozzle comprising a spray hole opened toward the stage and configured to spray a dual fluid through the spray hole;
a cover that comprises an inlet surrounding at least a partial area of an outer circumferential surface of the spray hole, that surrounds at least a partial area of an outer circumferential surface of the spray nozzle, and that is spaced apart from the spray nozzle by a predetermined distance; and
an air flow passage formed in a space between the cover and the spray nozzle and through which air sucked from the inlet flows.

2. The substrate cleaning apparatus of claim 1, wherein
the inlet surrounds an entire outer circumferential surface of the spray hole.

3. The substrate cleaning apparatus of claim 1, wherein
the inlet is disposed relatively closer to the stage than the spray hole.

4. The substrate cleaning apparatus of claim 1, wherein
the cover comprises a distal end portion extending to a position closer to the stage than the spray nozzle.

5. The substrate cleaning apparatus of claim 1, wherein
the cleaning unit comprises:
a gas line connected to the spray nozzle and configured to supply gas to the spray nozzle; and
a liquid line connected to the spray nozzle and configured to supply de-ionized water (DIW) to the spray nozzle.

6. The substrate cleaning apparatus of claim 5, wherein
the cover comprises:
a through hole through which the gas line and the liquid line pass; and
a sealing member provided in the through hole.

7. The substrate cleaning apparatus of claim 1, further comprising:
a chamber configured to accommodate the stage in the chamber.

8. The substrate cleaning apparatus of claim 7, wherein
the cleaning unit is configured to pass air sucked through the inlet through the air flow passage and discharge air to an outside of the chamber.

9. The substrate cleaning apparatus of claim 1, wherein
the stage comprises an outlet that is disposed in a direction surrounding the substrate disposed on the support unit and is configured to suck air from the stage.

10. The substrate cleaning apparatus of claim 1, wherein
the stage comprises a guard ring surrounding the substrate disposed on the support unit and extending to an upper part of the stage.
